(19) United States
(12) Patent Application Publication
(10) Pub. No.: US 2026/0303043 A1
(43) Pub. Date: Oct. 1, 2026

(54) LOW SPURIOUS DOWN-CONVERSION MIXER

(71) Applicant: Viasat, Inc., Carlsbad, CA (US)

(72) Inventors: David COPELAND, Wesley Chapel, FL (US); Chi W. SHUM, Chandler, AZ (US); Alberto RODRIGUEZ, Land O Lakes, FL (US); Miriam V. CALVO, Carlsbad, CA (US)

(21) Appl. No.: 19/490,262

(22) PCT Filed: Jun. 7, 2024
(86) PCT No.: PCT/US2024/033149

§ 371 Date: Dec. 4, 2025

Related U.S. Application Data
(60) Provisional application No. 63/472,196, filed on Jun. 9, 2023.

(51) Int. Cl. H03F 3/24; H03D 7/12; H04B 1/59

(52) U.S. Cl. CPC H03F 3/245; H03D 7/12; H04B 1/59; H03F 2200/294; H03F 2200/451

(57) ABSTRACT

Methods, systems, and devices for implementing a low spurious down-conversion mixer is described. For instance, a satellite transponder may amplify a first signal at a low noise amplifier of the satellite transponder and generate, at a local oscillator of the satellite transponder, an oscillator signal at an oscillator frequency. The satellite transponder may divide a first signal among two mixing subcircuits and, where each mixing subcircuit may output a respective component signal. The satellite transponder may combine the component signals output from the two mixing subcircuits to obtain the second signal with one or more odd harmonics of the oscillator frequency suppressed. In some examples, the satellite transponder may adjust a phase of phase shifters within two mixing subcircuits, where one or more even harmonics of the oscillator frequency may be suppressed based on the adjusting.

### CROSS REFERENCE

The present Application is a 371 national phase filing of International Patent Application No. PCT/US2024/033149 by COPELAND et al. entitled, “LOW SPURIOUS DOWN-CONVERSION MIXER”, filed Jun. 7, 2024, and to U.S. Provisional Patent Application No. 63/472,196 by COPELAND et al., entitled “LOW SPURIOUS DOWN-CONVERSION MIXER” filed Jun. 9, 2023, each of which is assigned to the assignee hereof and each of which is hereby incorporated by reference in its entirety.

### BACKGROUND

The following relates generally to communications, including a low spurious down-conversion mixer that may be used, for example, within a satellite communications system.

In some examples, a transponder may be capable of receiving a first signal and emitting a second signal in response. The transponder may, for instance, receive the first signal over a first range of frequencies and may emit the second signal over a second range of frequencies different from the first range of frequencies. A first device may transmit the first signal and a second device may receive the second signal. To generate the second signal, the transponder may amplify the first signal and may mix the first signal with a third signal generated by a local oscillator. Performing the amplifying and mixing may introduce distortions into the second signal that are not present in the first signal. As the second signal becomes more distorted, the second device may be less likely to correctly decode the second signal, thus decreasing the efficiency of communications between the first device and the second device.

### SUMMARY

The described techniques relate to improved methods, systems, devices, and apparatuses that supports a low spurious down-conversion mixer. For example, the described techniques provide for a satellite transponder to suppress mixing products within a band of a transmit signal. For instance, the satellite transponder may amplify a first signal at a low noise amplifier of the satellite transponder and generate, at a local oscillator of the satellite transponder, an oscillator signal at an oscillator frequency. The satellite transponder may divide the first signal among a two mixing subcircuits, where each mixing subcircuit may output a respective component signal. The satellite transponder may combine the component signals output from the set of mixing subcircuits to obtain the second signal with one or more harmonics of the oscillator frequency suppressed. In some examples, the satellite transponder may adjust a phase of a phase shifter between the mixing subcircuits, where one or more harmonics of the oscillator frequency may be suppressed based on the adjusting. Adjusting the phase shifter may suppress one or more combinatorial harmonics (e.g., of the oscillator frequency and the frequency of the first signal), but may reduce suppression of an even harmonic (e.g., of the oscillator frequency). In some cases, the even harmonic of the oscillator frequency may be suppressed based on adjusting a balance of the mixing subcircuits. In some cases, a combination of adjusting the phase shifter and balance of the mixing subcircuits may suppress both the even harmonic and the combinatorial harmonic. The satellite transponder may amplify the second signal at a power amplifier of the satellite transponder.

### BRIEF DESCRIPTION OF THE DRAWINGS

FIG. 1 shows an example of a satellite transponder signal diagram that supports a low spurious down-conversion mixer in accordance with examples described herein.

FIG. 2 shows an example of a satellite transponder that supports a low spurious down-conversion mixer in accordance with examples described herein.

FIG. 3 shows an example of a satellite transponder signal diagram that supports a low spurious down-conversion mixer in accordance with aspects of the present disclosure.

FIGS. 4A and 4B show examples of frequency domain responses that support a low spurious down-conversion mixer in accordance with aspects of the present disclosure.

FIGS. 5A and 5B show example graphs of time domain responses that support a low spurious down-conversion mixer in accordance with aspects of the present disclosure.

FIG. 6 shows an example of a satellite transponder signal diagram that supports a low spurious down-conversion mixer with double balanced mixers in accordance with aspects of the present disclosure.

FIG. 7 shows an example flowchart illustrating a method that supports low spurious down-conversion mixer in accordance with aspects of the present disclosure.

### DETAILED DESCRIPTION

Satellite communication systems may employ down-converters to convert from one radio frequency band to another. For example, a satellite may need to convert radio frequency signals in a Ka-band (e.g., 27.5-31 Giga Hertz (GHz)) to a K-band (17.7-21.2 GHz), which may entail stepping down the frequency of the received radio signal. To perform the down-conversion, a down-conversion mixer may be located on board the satellite.

However, conventional down-conversion mixers generate spurious tones that can result in noise or other errors in the converted signal. For example, spurious tones may be added to the band of the satellite's conversion bandwidth by the down-conversion mixer. Satellite communication systems may have strict spurious tone requirements for the given frequency (e.g., the specific frequency plan for the specific satellite). Techniques and apparatuses described herein suppress some of the spurious tones that are traditionally present due to the functionality of a down-conversion mixer.

A transponder may be capable of receiving an input radio frequency (RF) signal over a first band spanning a first range of frequencies and emitting an output RF signal over a second band spanning a second range of frequencies. Frequency conversion for the transponder may be performed using indirect conversion where the input RF signal may be mixed with a first oscillator signal to generate an intermediate frequency signal, and then the intermediate frequency signal may be mixed with a second oscillator signal to generate the output RF signal. Frequency conversion for the transponder may also be performed using direct conversion where the input RF signal is mixed with a single oscillator signal generated by a local oscillator to obtain the output RF signal directly without generating the intermediate frequency signal. For indirect conversion, the oscillator signals (e.g., first oscillator signal and second oscillator signal) are generally relatively close to the first band or second band. For example, if the first band is centered around 30 GHz and the second band is centered around 20 GHz, the first and second oscillator signals may be 28 GHz and 18 GHZ, such that the intermediate frequency signal is centered around 2 GHz. In this case, harmonics and mixing products of the oscillator signals and the input RF signal may not generally be within the second band (the band of the output RF signal) such that they cause distortion in the output RF signal. For example, the harmonics of the first, 28 GHz oscillator signal (e.g., 56 GHZ, 84 GHZ) may be higher than the second band. For direct conversion, however, it is more likely that harmonics of the oscillator signal and mixing products of the oscillator signal and the input RF signal are within the band of the output RF signal, causing distortion in the output RF signal.

Using direct conversion, mixing the input RF signal with the oscillator signal may thus introduce distortions from the oscillator harmonics or mixing products (e.g., due to a non-linearity associated with the mixer performing the mixing). If these mixing products are located outside of the second band, the direct-conversion transponder may suppress these mixing products using a bandpass filter. However, if these mixing products are located within the second band, a bandpass filter may not be sufficient for suppressing the mixing products within the second band without suppressing other, desired portions of the second band (e.g., the output RF signal). A single down-conversion architecture with a local oscillator (LO) having a fixed frequency of 9.8 GHz, for example, is simple and power efficient but suffers from in-band spurious generation. There may be large in-band spurs at frequencies of two times the frequency of the local oscillator (2×LO) and at five times the local oscillator minus the input RF signal frequency (5×LO-RF).

A single double balanced mixer naturally provides some reduction of all even-order spurs, including the 2×LO. Poly-phasing is a technique using multiple mixers to cancel out additional harmonics. For example, poly-phasing using N mixers generally suppresses harmonics up to (but not including) the N+1 harmonic. However, the power consumption of poly-phase mixers increases substantially with each additional phase that is added to eliminate spurs that may not be in-band anyway, and a large number of mixers would be needed to eliminate higher-order mixing products. In addition, each additional mixer may introduce additional imbalances, and may include its own balancing circuits, increasing complexity for each additional mixer. If the mixers were perfect, without any coupling, and they were perfectly balanced, there would be no 2×LO spur. But because of inaccuracies in the transistors the mixers are made from, other non-poly phasing compensation techniques may be used to further reduce the even-order spurs. Specifically, imbalances can be deliberately introduced in the mixers until the natural imbalances in the transistors are canceled out, and the 2×LO spur is suppressed.

In some cases, a higher-order mixing product such as the 5×LO-RF odd-order spur is in band and may need suppression. According to aspects described herein, harmonics and/or mixing products for a direct conversion transponder may be suppressed within the second band using a mixing circuit that employs a two mixing subcircuits for mixing the input RF signal with the oscillator signal. For instance, the mixing circuit may include a splitting circuit configured to divide the input RF signal among the two mixing subcircuits. At least one of the mixing subcircuits may include a phase shifter configured to output a phase-shifted representation of the oscillator signal generated by the local oscillator, and a mixer configured to mix the input RF signal and the phase-shifted oscillator signal. The signals output by the respective mixer of each mixing subcircuit of the set of mixing subcircuits may be combined by a combining circuit of the mixing circuit and the combined signal may be output as the output RF signal, where the output RF signal may undergo amplification and/or filtering before being emitted. In some examples, the input RF signal may undergo amplification and/or filtering before being divided by the splitting circuit.

The phase shifter of may shift a phase of the oscillator signal by an amount selected such that one or more mixing products of odd harmonics of the oscillator frequency associated with the local oscillator are suppressed when the combining circuit combines the signals output by the mixers of the two mixing subcircuits. For instance, the fifth harmonic of the oscillator frequency minus the RF of the input signal may be suppressed when the signals output by the two mixing subcircuits are combined by the combining circuit. If the mixing products within the second band are aligned with a harmonic of the oscillator frequency suppressed by the mixing circuit, then the mixing products may also be suppressed. In this manner, the mixing products within the second band that may impact the output RF signal may be suppressed.

In some examples, the direct-conversion transponder may include a controller configured to send a command to the mixing circuit that indicates for the mixing circuit to adjust respective phases of a first phase shifter of a mixing subcircuit. Additionally, in examples in which each mixing subcircuit includes a respective amplitude adjustment circuit (e.g., a circuit configured to adjust an amplitude of the first signal), the controller may be configured to send a second command to the mixing circuit that indicates for the mixing circuit to adjust respective amplitudes of the amplitude adjustment circuit for a mixing subcircuit of the two mixing subcircuits. Adjusting phases of the first phase shifters and adjusting amplitudes of amplitude adjustment circuits may enable more effective suppression of the one or more harmonics of the oscillator frequency.

In some examples, a subset of harmonics of the oscillator frequency may not be suppressed by a single mixer that is not double-balanced. To suppress the subset of harmonics, the mixing circuit may be double-balanced, which may be used to suppress any even harmonics. For instance, the mixing circuit may include a set of differential mixers that are each coupled with a first splitting circuit and a second splitting circuit, where the first splitting circuit is configured to receive a first input RF signal and the second splitting circuit is configured to receive a second input RF signal, and where the first input RF signal and the second input RF signal are a differential pair of signals. Each differential mixer may output a respective first component signal associated with the first input RF signal to a first combining circuit and a respective second component signal associated with the second input RF signal to a second combining circuit. The first combining circuit may combine the respective first component signals from the set of differential mixers and may output a third signal. Additionally, the second combining circuit may combine the respective second component signals from the set of differential mixers and may output a fourth signal. A phase shifter may be present between a local oscillator and at least one differential mixer. In some examples, suppressing the even harmonics may occur more effectively if balances of the differential mixers are adjusted. Thus, the mixing circuit may include one or more balance adjustment circuits to adjust a balance of the differential mixers.

Aspects of the disclosure are described in the context of satellite transponder signal diagrams and a satellite transponder. Additional aspects of the disclosure are described in the context of frequency domain responses.

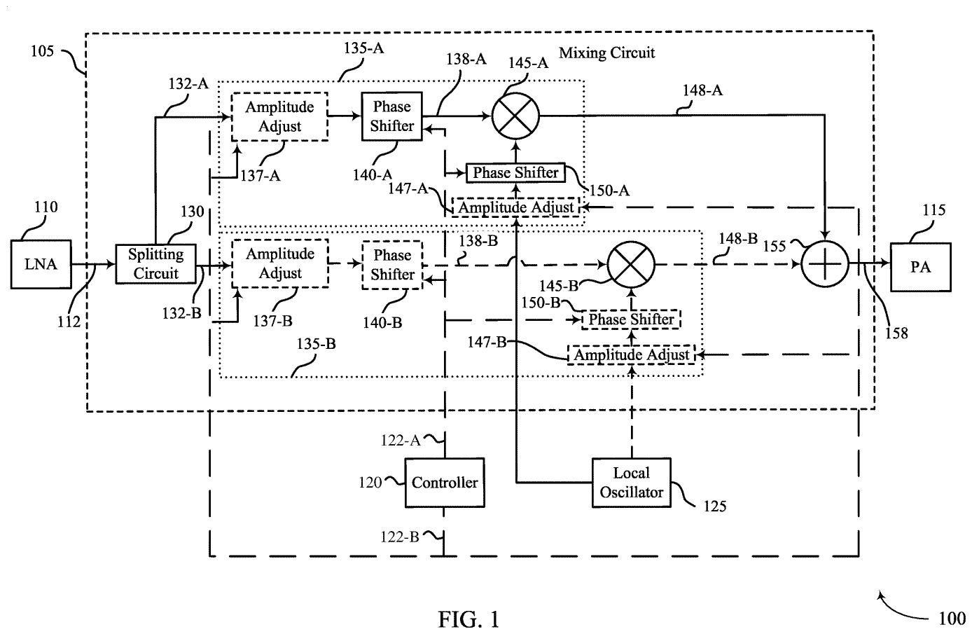

FIG. 1 shows an example of a satellite transponder signal diagram 100 that supports a low spurious down-conversion mixer in accordance with examples described herein. The satellite transponder signal diagram 100 may include two mixers, wherein phase shifting is applied to suppress a 5×LO-RF spur, and in-balance controls are applied on the mixer to suppress the 2×LO spur. In some examples, the satellite transponder may operate on a bent pipe principle.

Satellite transponder signal diagram 100 may include a low noise amplifier (LNA) 110. LNA 110 may be coupled with a mixing circuit 105. Mixing circuit 105 may be coupled with a power amplifier (PA) 115, a controller 120, and a local oscillator 125. Mixing circuit 105 may include a splitting circuit 130 coupled with LNA 110. Additionally, mixing circuit 105 may include a first mixing subcircuit 135-a and a second mixing subcircuit 135-b, both coupled with splitting circuit 130. Mixing circuit 105 may also include a combining circuit 155 coupled with first mixing subcircuit 135-a and second mixing subcircuit 135-b, as well as PA 115.

First mixing subcircuit 135-a may include a first phase shifter 140-a, a mixer 145-a, and, in some examples, a second phase shifter 150-a. Second mixing subcircuit 135-b may include a first phase shifter 140-b, a mixer 145-b, and, in some examples, a second phase shifter 150-b. In some examples, first mixing subcircuit 135-a may include an amplitude adjustment circuit 137-a and second mixing subcircuit 135-b may include an amplitude adjustment circuit 137-b. In such examples, amplitude adjustment circuit 137-a may be coupled with splitting circuit 130 and first phase shifter 140-a. Amplitude adjustment circuit 137-b may be coupled with splitting circuit 130 and first phase shifter 140-b. In other examples, first phase shifters 140-a and 140-b may be directly coupled with splitting circuit 130 (e.g., amplitude adjustment circuits 137-a and 137-b may not be present). In some examples, first mixing subcircuit 135-a may include amplitude adjustment circuit 147-a and second mixing subcircuit 135-b may include amplitude adjustment circuit 147-b. In such examples, amplitude adjustment circuit 147-a may be coupled with local oscillator 125 and second phase shifter 150-a, while amplitude adjustment circuit 147-b may be coupled with local oscillator 125 and second phase shifter 150-b. Optionally in some examples, second phase shifters 150-a and 150-b may be directly coupled with local oscillator 125 (e.g., amplitude adjustment circuits 147-a and 147-b may not be present).

First phase shifter 140-a and second phase shifter 150-a may be coupled with mixer 145-a. First phase shifter 140-b and second phase shifter 150-b may be coupled with mixer 145-b. Mixers 145-a and 145-b may be coupled with combining circuit 155. In some examples, one or more of first phase shifters 140-a and 140-b and second phase shifters 150-a and 150-b may be coupled with controller 120. In some examples, amplitude adjustment circuits 137-a and 137-b may be coupled with controller 120.

In some examples, satellite transponder signal diagram 100 may illustrate techniques for suppressing one or more harmonics of an oscillator frequency. For instance, LNA 110 may receive a first signal (e.g., input RF signal) in a first band spanning a first frequency range (e.g., via an antenna). LNA 110 may amplify the first signal and may provide the amplified first signal to mixing circuit 105. Mixing circuit 105 may be configured to frequency convert the first signal to a second signal and to suppress one or more harmonics of the oscillator frequency. For instance, LNA 110 may provide the amplified first signal to splitting circuit 130 and splitting circuit 130 may divide the first signal between first mixing subcircuit 135-a and second mixing subcircuit 135-b. The splitter circuit may be configured to divide the first signal to obtain a first input component signal 132-a and a second input component signal 132-b. Splitting circuit 130 may provide the first signal to amplitude adjustment circuits 137-a and 137-b or may provide the first signal to first phase shifters 140-a and 140-b (e.g., in examples in which amplitude adjustment circuits 137-a and 137-b are not present). Amplitude adjustment circuits 137-a and 137-b, upon receiving the first signal, may adjust an amplitude of the first signal by a respective amount and may provide the first signal to first phase shifters 140-a and 140-b, respectively. First phase shifters 140-a and 140-b, upon receiving the first signal, may output a respective phase shifted representation of the first signal and may provide the respective phase shifted representation to mixers 145-a and 145-b, respectively. The first phase shifter 140-a may output a phase shifted oscillator signal 138-a.

Additionally, local oscillator 125 may provide an oscillator signal 127 to amplitude adjustment circuits 147-a and 147-b or may provide the oscillator signal 127 to second phase shifters 150-a and 150-b (e.g., in examples in which amplitude adjustments circuits 147-a and 147-b are not present). Amplitude adjustment circuits 147-a and 147-b, upon receiving the oscillator signal 127, may adjust an amplitude of the oscillator signal 127 by a respective amount and may provide the oscillator signal 127 to second phase shifters 150-a and 150-b, respectively. Second phase shifters, upon receiving the oscillator signal 127, may output a respective phase shifted representation of the oscillator signal 127 and may provide the respective phase shifted representation of the oscillator signal 127 to mixers 145-a and 145-b, respectively. It should be noted that the oscillator signal 127 may be split using a splitting circuit as described herein.

Mixer 145-a, upon receiving the respective phase shifted representation of the first signal from first phase shifter 140-a and the respective phase shifted representation of the oscillator signal 127 from second phase shifter 150-a, may mix the respective phase shifted representation of the first signal and the respective phase shifted representation of the oscillator signal and may output a first component signal 148-a. Similarly, mixer 145-b, upon receiving the respective phase shifted representation of the first signal from first phase shifter 140-b and the respective phase shifted representation of the oscillator signal 127 from second phase shifter 150-b, may mix the respective phase shifted representation of the first signal and the respective phase shifted representation of the oscillator signal 127 and may output a second component signal 148-b. Mixers 145-a and 145-b may provide the first and second component signals, respectively, to combining circuit 155.

Combining circuit 155 may combine (e.g., sum or subtract) the first and second component signals 148-a and 148-b, to obtain the second signal 158 in a second band spanning a second frequency range and may provide the second signal 158 to PA 115. PA 115 may amplify the second signal 158 and may output the amplified second signal (e.g., to an antenna). In some examples, the oscillator frequency of the oscillator signal 127 output by local oscillator 125 may correspond to (e.g., be equal to or approximately equal to) a difference between a lowest frequency of the second frequency range of the second band and a lowest frequency of the first frequency range of the first band. Additionally, the frequency-converting performed by mixing circuit 105 may convert first signal 112 associated with the first range to second signal 158 associated with the second frequency range.

In order to suppress harmonics of the oscillator frequency, first phase shifters 140-a and 140-b and second phase shifters 150-a and 150-b may be configured to shift the phase of the first signal 112 and the oscillator signal 127, respectively, such that the resulting component signals 148-a and 148-b cancel with each other at certain harmonics (e.g., the fifth harmonic, the seventh harmonic) and mixing products and not at others (e.g., the fundamental harmonic). In some cases, first phase shifters 140-a and 140-b may not be present, and the fundamental for mixers 145-a and 145-b may be combined by combining circuit 155, where the combining may include summation or subtraction, depending on the relative phases of one or more of second phase shifters 150-a and 150-b. Alternatively one or more of first phase shifters 140-a and 140-b may be present, and the combining may include summation or subtraction, depending on the relative phases of one or more of first phase shifters 140-a and 140-b and second phase shifters 150-a and 150-b. Additionally or alternatively, first phase shifters 140-a and 140-b may be present to account for path length differences, and may thus be used to calibrate mixers 145-a and 145-b to receive in-phase signals.

In some examples, mixing circuit 105 may not suppress harmonics optimally (e.g., due to nonlinearities or physical properties associated with the mixing circuit 105). Additionally, higher order mixing products (e.g., 5×LO-RF) may not be suppressed by mixing circuit 105. In some cases, a phase shift for the oscillator signal may be introduced using, for example, phase shifter 150-a to suppress a higher order mixing product. The amount of the phase shift may be selected such that the mixing product at the first mixer 145-a may cancel with the mixing product in the second mixer 145-b, such that the higher order mixing product is suppressed when the second signals 148-a and 148-b are combined by combining circuit 155. The phase shift for the oscillator signal may reduce the ability of the mixing circuit 105 to reduce an even order harmonic, and balance of mixers 145-a and 145-b may be adjusted to suppress the even order harmonic that was enhanced by the phase shift introduced by the phase shifter 150-a.

Mixing circuit may include additional adjustment capability to enable greater suppression of harmonics. For example, a controller 120 may adjust the amount that first phase shifters 140-a and 140-b and/or second phase shifters 150-a and 150-b adjust phase. For instance, controller 120 may send a command 122-a to mixing circuit 105 indicating for mixing circuit 105 to adjust respective phases of at least one of first phase shifters 140-a and 140-b and/or second phase shifters 150-a and 150-b. Additionally, the controller 120 may adjust the amount by which amplitude adjustment circuits 137-a and 137-b and/or amplitude adjustment circuits 147-a and 147-b adjust amplitude. For instance, controller 120 may send a second command 122-b to mixing circuit 105 that indicates for mixing circuit 105 to adjust respective amplitudes of at least one of amplitude adjustment circuits 137-a, 137-b, 147-a, and 147-b. In some examples, how much first phase shifters 140-a and 140-b, second phase shifters 150-a and 150-b, and/or amplitude adjustment circuits 137-a, 137-b, 147-a, and 147-b are adjusted may be dependent on a temperature associated with the satellite transponder (e.g., a temperature of the transponder).

The techniques described herein provide a power efficient means to directly convert signals between frequency bands, with very low in-band spurious products. In some examples, the techniques described herein may be associated with one or more advantages. For instance, suppressing mixing products may reduce an amount of distortion within a band of a signal transmitted from the transponder. Reducing the amount of distortion may increase a likelihood that a receiving device successfully decodes the signal. Techniques described herein perform a reduced amount of phase shifting (using a minimum amount of phase shifters) on one mixer, without phase shifting a second mixer. By shifting one mixer by a first amount with respect to the other mixer, a mixing product (e.g., the 5×LO-RF harmonic) may be suppressed. This may result in only a slight decrease in the gain, because the fundamental frequency is only shifted by a small amount while the mixing product may be shifted by a full half-cycle, resulting in suppression at the combining circuit 155. The techniques and apparatuses described herein suppress the largest in-band spurs, which may be the most important, and do so with substantial (e.g., more than a 30%) current drain savings and with fewer controls. Techniques described herein need less calibration and less current than other solutions employing more than two mixers. Techniques using multiple phase shifters and multiple imbalance controls are very involved, and the current drain may be significant. Techniques described herein achieve suppression of the most important spurs, while using fewer mixers and calibration controllers. Furthermore, the apparatus described herein may be symmetrically laid out on a die, thus providing better circuit device matching while saving size and weight of the die.

For example, the techniques described herein may have advantages over solutions using three or more mixing subcircuits, because it may use only two mixers, which reduces the size, weight, and power (SWAP). For example, the two mixer solution may use less current to suppress the largest spurs (e.g., one-third of the current may be saved for the two mixer solution over a three mixer solution). The techniques described herein may have further advantages over global feedback mitigation techniques (e.g., usage of operation amplifiers), which may lack sufficient loop gain at gigahertz (GHz) bands. Additionally, or alternatively, the techniques described herein may have advantages over filtering mitigation techniques (e.g., use of a filter to suppress harmonics) as the roll-off may be limited and in-band spurs may be difficult to suppress.

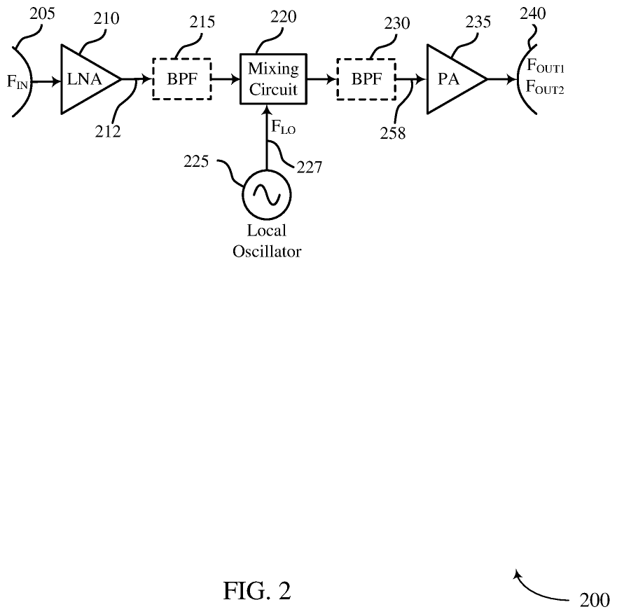

FIG. 2 shows an example of satellite transponder 200 that supports a low spurious down-conversion mixer in accordance with aspects of the present disclosure. In some examples, satellite transponder 200 may include one or more aspects of satellite transponder signal diagram 100. For instance, LNA 210 may be an example of an LNA 110 as described with reference to FIG. 1; mixing circuit 220 may be an example of a mixing circuit 105 as described with reference to FIG. 1; PA 235 may be an example of a PA 115 as described with reference to FIG. 1; local oscillator 225 may be an example of a local oscillator 125 as described with reference to FIG. 1; or any combination thereof.

Antenna 205 may be coupled with LNA 210. Antenna 205 may be, for example, a phased array antenna, a direct-radiating phased array antenna, a phased array fed reflector (PAFR) antenna, or any other type of antenna known in the art for transmission and/or reception of signals. LNA 210 may be coupled with bandpass filter 215 or may be directly coupled with mixing circuit 220 (e.g., if bandpass filter 215 is not present). Mixing circuit 220 may be coupled with local oscillator 225 and bandpass filter 230. In some examples, mixing circuit 220 may be coupled directly with PA 235 (e.g., if bandpass filter 230 is not present). PA 235 may be coupled directly with antenna 240. In some cases, antenna 205, LNA 210, and bandpass filter 215 may be part of an antenna system, which may include a beamformer (e.g., an analog beamformer).

In some examples, satellite transponder 200 may illustrate techniques for frequency conversion in which one or more oscillator harmonics are suppressed. For instance, antenna 205 may receive a first signal (e.g., a first signal with frequency F_{IN}) in a first band and may provide the first signal to LNA 210. LNA 210 may amplify the first signal and may provide the first signal 212 to bandpass filter 215 or mixing circuit 220 (e.g., if bandpass filter 215 is not present). Bandpass filter 215 may filter the first signal 212 to be within the first band and may provide the first signal 212 to mixing circuit 220.

Mixing circuit 220 may frequency-convert the first signal 212 in the first band to a second signal 258 in a second band using an oscillator signal 227 from local oscillator 225, where mixing products formed via the mixing process may be suppressed using the low spurious down-conversion mixer. For instance, the mixing products may be aligned with (e.g., at a same frequency as) one or more suppressed harmonics of an oscillator frequency of the oscillator signal output by local oscillator 225 and may thus be suppressed in a similar fashion as the one or more suppressed harmonics are suppressed. A suppressed harmonic may be reduced in amplitude or canceled.

The mixing circuit 220 may provide the second signal to bandpass filter 230 or may provide the second signal to PA 235 (e.g., in examples in which bandpass filter 230 is not present). Bandpass filter 230 may filter the second signal to be within the second band and may provide the second signal to PA 235. PA 235 may amplify the second signal and may provide the second signal to antenna 240. Antenna 240 may transmit the second signal (e.g., at a frequency F_{OUT1} or a frequency F_{OUT2}, where F_{OUT1}=F_{IN}−F_{LO} and F_{OUT2}=F_{IN}+F_{LO}). Antenna 240 may be, for example, a phased array antenna, a direct-radiating phased array antenna, a PAFR antenna, or any other type of antenna known in the art for transmission and/or reception of signals. In some cases, antenna 240, PA 235, and bandpass filter 230 may be part of an antenna system, which may include a beamformer (e.g., an analog beamformer).

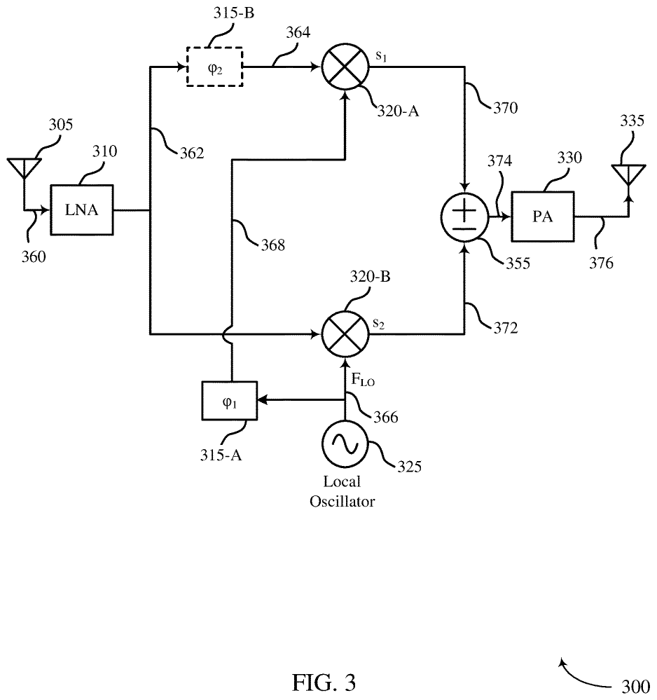

FIG. 3 shows an example of a satellite transponder signal diagram 300 that supports a low spurious down-conversion mixer in accordance with aspects of the present disclosure. In some examples, satellite transponder signal diagram 300 may implement one or more aspects of satellite transponder signal diagram 100 and/or satellite transponder 200. For instance, antenna 305 may be an example of an antenna 205 as described with reference to FIG. 2; LNA 310 may be an example of an LNA 110 as described with reference to FIG. 1 and/or an LNA 210 as described with reference to FIG. 2; phase shifters 315-a and 315-b may each be an example of any of phase shifters 140-a, 140-b, 150-a, or 150-b as described with reference to FIG. 1; local oscillator 325 may be an example of any of local oscillator 125 as described with reference to FIG. 1 and local oscillator 225 as described with reference to FIG. 2; mixers 320-a and 320-b may each be an example of any of mixers 145-a and 145-b as described with reference to FIG. 1; combining circuit 355 may be an example of a combining circuit 155 as described with reference to FIG. 1; PA 330 may be an example of a PA 115 as described with reference to FIG. 1 or a PA 235 as described with reference to FIG. 2; antenna 335 may be an example of antenna 240 as described with reference to FIG. 2; or any combination thereof.

Antenna 305 may be coupled with LNA 310, and antenna 305 may provide an input frequency signal 360 to LNA 310. LNA 310 may be coupled (e.g., via a splitter) with mixers 320-a and 320-b. LNA 310 may amplify the input frequency signal 360 and provide a first signal 362 to phase shifter 315-b (or mixer 320-a if phase shifter 315-b is not present) and to mixer 320-b. In examples where phase shifter 315-b is present, the phase shifter 315-b may shift the phase of first signal 362 to generate imbalanced signal 364. Second phase shifter 315-b may be optional, so in some examples it is not present. Second phase shifter 315-b may be used to better balance the RF path (e.g., in cases where the paths between LNA 310 and mixers 320-a and 320-b are not equal). However, second phase shifter 315-b may not be needed if the RF paths are sufficiently balanced that the 2×LO spur is not a concern (e.g., if the phase is not identical due to circuit non-idealities). Second phase shifter 315-b may be a fine shifter, where small amounts of phase shifting may be applied. For example, φ₂ may be less than 1 degree.

Local oscillator 325 may be coupled to phase shifter 315-a and mixer 320-b. Local oscillator 325 may provide oscillator signal 366 to phase shifter 315-a and mixer 320-b. Phase shifter 315-a may be coupled to mixer 320-a and provide it with shifted signal 368. Mixers 320-a and 320-b may be coupled with combining circuit 355. Mixer 320-a may provide first output component signal 370 to combining circuit 355. Mixer 320-b may provide second output component signal 372 to combining circuit 355. Combining circuit 355 may be coupled with PA 330 and provide a second signal 374 to PA 330. PA 330 may be coupled with antenna 335 and provide an amplified second signal 376 to antenna 335.

The signals 362, 364, 366, 368, 370, 372, and 374 may be differential signals. Similarly, LNA 310, phase shifters 315-a and 315-b, local oscillator 325, mixers 320-a and 320-b, combining circuit 355, and power amplifier 330 may be differential components.

In some examples, satellite transponder signal diagram 300 may illustrate techniques for frequency conversion in which one or more oscillator harmonics are suppressed. For instance, antenna 305 may receive a first signal in a first band and may provide the first signal to LNA 310. LNA 310 may amplify the first signal and may provide the first signal to mixers 320-a and 320-b (e.g., via a splitter). The local oscillator 225 may output oscillator signal 366, which may be used to frequency convert the first signal. First phase shifter 315-a may shift the oscillator signal 366 by φ₁, and may provide the phase shifted oscillator signal to mixer 320-a. In some examples, φ₁ may be selected based on an order of a harmonic of the LO to be suppressed. For example, with respect to the odd order LO harmonic spurs, a formula for the phase shift, assuming the combining circuit 355 subtractive circuit, may be given as

$${φ}_{1} = 180 ( 1 - \frac{1}{n} ) ,$$

where n is the LO harmonic of the spur to be suppressed (e.g., the fifth order harmonic). This equation may apply for all odd orders of the LO harmonic. In examples where the combining circuit is a summation circuit, the formula may differ. For example, when the combining circuit 355 is a summing circuit, the formula for the phase shift may be given as

$${φ}_{1} = \frac{360}{2 n} .$$

As described above, the phase shift φ₂ for the second phase shifter 315-b may be dependent upon the path length difference for the paths between LNA 310 and mixers 320-a and 320-b, and may be a relatively small phase shift (e.g., a smaller phase shift than φ₁).

Mixers 320-a and 320-b may be gilbert cell quad double-balanced mixers. They may have independent transistors (e.g., current source legs) that each have a bias pin that takes a DC voltage input. For example, mixers 320-a and 320-b may be differential mixers, each having a P side and an N side. Each one of the sides may have a bias voltage that adjusts the balance of the mixer. The bias level of the P side may be changed to be different than that on the N side. That is, the imbalances can be compensated for by adjusting the DC bias points on the P side versus the N side of the differential nodes within the Gilbert quad. This enables the mixers 320-a and 320-b to be balanced, because the inputs can be changed individually to balance them to compensate for on-chip mismatch. This technique may change the gain somewhat, but may be used to suppress even-order spurs.

In comparison to poly-phase mixer solutions, one spur (e.g., 5×LO-RF) may be suppressed using an LO phase shift that is dependent upon the spur (e.g., order of the odd harmonic) at the expense of another (e.g., 2×LO), and then a different non-poly phase method (e.g., adjusting mixer balance) may be used to suppress that spur (e.g., 2×LO). In contrast, a poly-phase mixer having a high enough order to suppress the 2×LO spur and higher order mixing products such as 5×LO-RF would draw substantially (e.g., 2.5 times) more current, be more complicated to calibrate, use more components, and have a greater size and weight. In addition, design and layout of such a mixer in an integrated circuit would be challenging due to the quantity of mixers. Using the present techniques including adjusting an offset of a phase of an oscillator signal to one of two mixers in combination with adjusting the imbalances of the mixers may suppress the spurs that are in-band (e.g., 2×LO, 5×LO-RF) with substantially simpler and smaller circuits that save space and power.

To determine the phase shift for the phase shifters and imbalance settings for the mixers, a gradient descent technique may be used to calibrate them. The 5×LO-RF spur may be suppressed first, then a gradient may be determined for the 2×LO spur, which is iterated to converge on phase shift and bias point offset amounts in the calibration process. The gradient descent may be applied to a limited quantity of controls. For example, the controls that may be calibrated in the gradient descent may include the phase shift φ₁ of the first phase shifter, and an offset between N and P sides for the two mixers, which thus may involve three controls. Optionally, the phase shift φ₂ of the second phase shifter may also be adjusted. In some cases, the bias points for the N and P sides of the two mixers may be adjusted separately. Because this solution implements fewer controls (e.g., 3-5 controls instead of 9 or more for at least a third order mixer), this solution is faster and easier to calibrate.

Mixer 320-a may mix the first signal with signal cos (ω_{LO}t−φ₁), where ω_{LO} may correspond to an oscillator frequency of local oscillator 225 and t may represent a time variable. Mixer 320-b may mix the first signal with signal cos (ω_{LO}t). After performing the mixing, mixer 320-a may output a first component signal (e.g., component signal s₁) and mixer 320-b may output a second component signal (e.g., component signal s₂). The first component signal and the second component signal may be provided to combining circuit 355. Combining circuit 355 may combine the first component signal and the second component signal, which may be an addition or subtraction operation. Combining each of the component signals may enable combining circuit 355 to obtain the second signal in a second band. The second signal may be provided by combining circuit 355 to PA 330 and PA 330 may amplify the second signal. PA 330 may provide the amplified second signal to antenna 335. Antenna 335 may transmit the amplified second signal.

In some examples (e.g., for frequency translation), mixers 320-a and 320-b may be configured to perform down-conversion and phase-shifting functions and may be examples of analog mixers. Using mixers 320-a and 320-b to perform phase-shifting functions may enable a wider band to be used than if phase shifters were used for this purpose. In some examples, mixers 320-a and 320-b may be modeled as non-linear circuits.

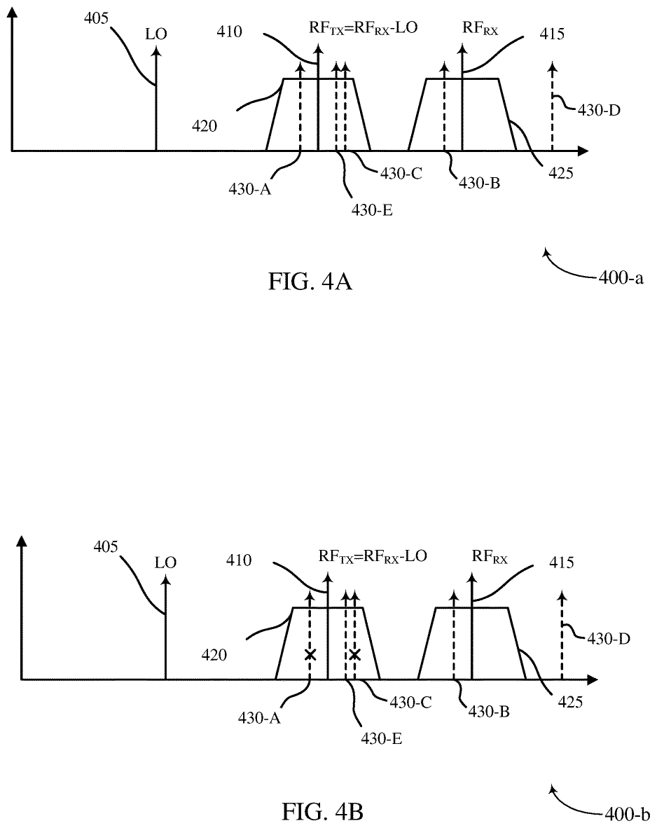

FIGS. 4A and 4B show examples of frequency domain responses 400-a and 400-b that support a low spurious down-conversion mixer in accordance with aspects of the present disclosure. In some examples, one or more aspects of FIGS. 4A and 4B may represent signals associated with one or more aspects of satellite transponder signal diagram 100 and/or 300 or satellite transponder 200. For instance, local oscillator frequency 405 may correspond to a frequency of a signal output by local oscillator 125 of FIG. 1 or a signal output by local oscillator 225 of FIG. 2 or 3. Additionally, or alternatively, transmit frequency 410 may represent a frequency of, and transmit frequency profile 420 may represent a band of, a signal produced by mixing circuit 105 of FIG. 1, a signal produced by mixing circuit 220 of FIG. 2, and/or a signal produced by combining circuit 355 of FIG. 3. Additionally, or alternatively, receive frequency 415 may represent a frequency of, and receive frequency profile 425 may represent a band of, a signal received by mixing circuit 105 of FIG. 1, a signal received by mixing circuit 220 of FIG. 2, and/or a signal output by LNA 310 of FIG. 3.

As depicted in FIG. 4A, a signal provided from an LNA may have a receive frequency 415 (e.g., a center frequency RF_{RX}) and may have a receive frequency profile 425 within a first frequency range. Additionally, a signal provided by a local oscillator may have an oscillator frequency 405 (e.g., oscillator frequency LO). After the signal provided from the LNA and the signal provided by the local oscillator are input to a single-phase mixer, a second signal may be generated by the single-phase mixer that may have a transmit frequency 410 (e.g., a center frequency RF_{TX}) and a transmit frequency profile 420 associated with a second frequency range. In some examples, the transmit frequency 410 may be dependent on the receive frequency 415 and the oscillator frequency 405 (e.g., RF_{TX}=RF_{RX}−LO).

In some examples, a single-phase mixer mixing the signal provided from the LNA and the signal provided from the local oscillator may generate one or more mixing products. For instance, mixing products 430-a, 430-b, 430-c, 430-d, 430-e, may be generated. Some of the mixing products may be outside of the second frequency range associated with transmit frequency profile 420. For instance, mixing products 430-b and 430-d may be outside of the second frequency range. Thus, a bandpass filter may be used to filter out mixing products 430-b and 430-d without affecting the transmit frequency profile 420. In some examples for using direct down-conversion, LO may be less than half of RF_{RX}, such that RF_{TX}>LO. For example, RF_{RX} may be approximately 30 GHz and LO may be approximately 10 GHz. However, mixing products 430-a, 430-c, and 430-e may be inside of the second frequency range. In such examples, using a bandpass filter to filter out these mixing products may affect the transmit frequency profile 420 since there is overlap between frequencies of the transmit frequency profile 420 and these mixing products.

Using a mixer, which may be a single double balanced mixer, as described herein may enable suppression or cancellation of one or more harmonics of the oscillator frequency 405. The mixing products 430-a, 430-b, 430-c, 430-d, and 430-e may be harmonics of the local oscillator. These may include a second harmonic 430-a (e.g., 2*ω which is 2×LO), a third harmonic 430-b (e.g., 3*ω), a fifth harmonic 430-c (e.g., 5*ω which is 5×LO-RF), a sixth harmonic 430-d (e.g., 6*ω), and an eighth harmonic 430-e (e.g., 8*ω which is 8×LO-2×RF) of oscillator frequency 405. In other examples, other values of RF and LO are possible which may provide for different mixing products being in-band or out-of-band.

As shown in FIG. 4B, use of the phase shifter to phase shift the oscillator signal input to one of the mixers by a phase shift that is dependent upon a spur to be suppressed may suppress the 5LO-RF spur, associated with the fifth harmonic 430-c, where RF may be equivalent to RF_{RX}. In some examples, the value of RF may be approximately a multiple of LO (e.g., RF~2LO, 3LO, etc.). Additionally, the single double balanced mixer may not suppress the even ordered harmonics, such as the second harmonic 430-a (e.g., 2×LO). However, adjustment of the balance for a double-balanced mixer as described herein may be used to suppress one or more even harmonics.

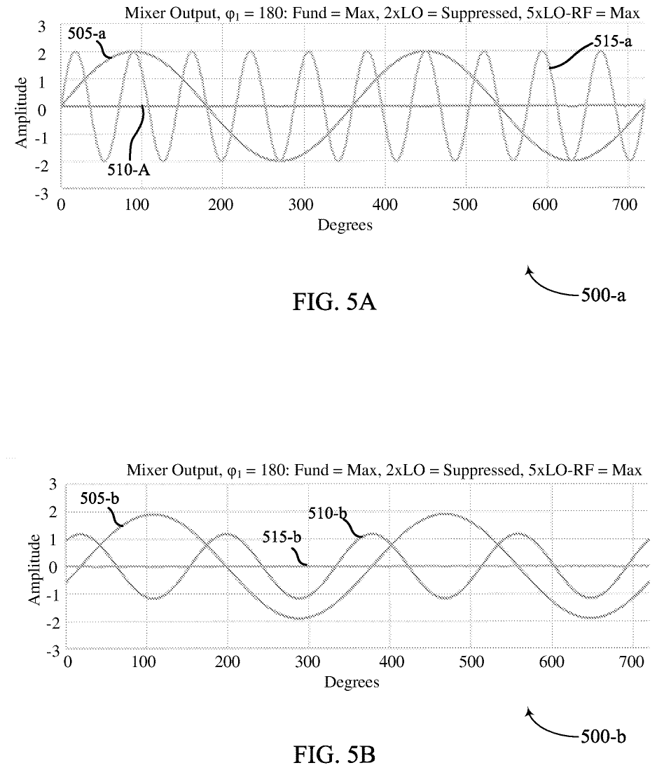

FIGS. 5A and 5B show examples of graphs 500-a and 500-b that support a low spurious down-conversion mixer in accordance with aspects of the present disclosure. In some examples, one or more aspects of FIGS. 5A and 5B may represent signals associated with one or more aspects of satellite transponder signal diagram 100 and/or 300 or satellite transponder 200. For instance, local oscillator frequency 505 may correspond to a frequency of a signal output by local oscillator 125 of FIG. 1 or a signal output by local oscillator 225 of FIG. 2.

Graphs 500-a and 500-b illustrate amplitude over phase for a fundamental frequency (e.g., the LO frequency) 505-a and 505-b, respectively, a 2× spur 510-a and 510-b, respectively, and a 5× spur 515-a and 515-b, respectively. Graph 500-a illustrates an example where the phase shift, φ₁, is 180 degrees. In this example, φ₁ being 180 degrees suppresses 2×LO completely, but does not suppress the large 5×LO-RF spur. In contrast, if φ₁ is set to a phase shift that is dependent on the order of the spur (e.g., 144 degrees when the combining circuit subtracts the signals or 36 degrees when the combining circuit sums the signals), there is suppression of the 5×LO-RF spur, and some reduction in 2×LO spur. As discussed above, the 2×LO spur that is enhanced by the phase shift of the oscillator signal may be suppressed by deliberately introducing the imbalance in the mixer to compensate for it, with gradient descent used to fine tune the phase shift of the oscillator signal and the imbalance in the mixer to achieve suppression of both the 5×LO-RF and 2×LO spurs.

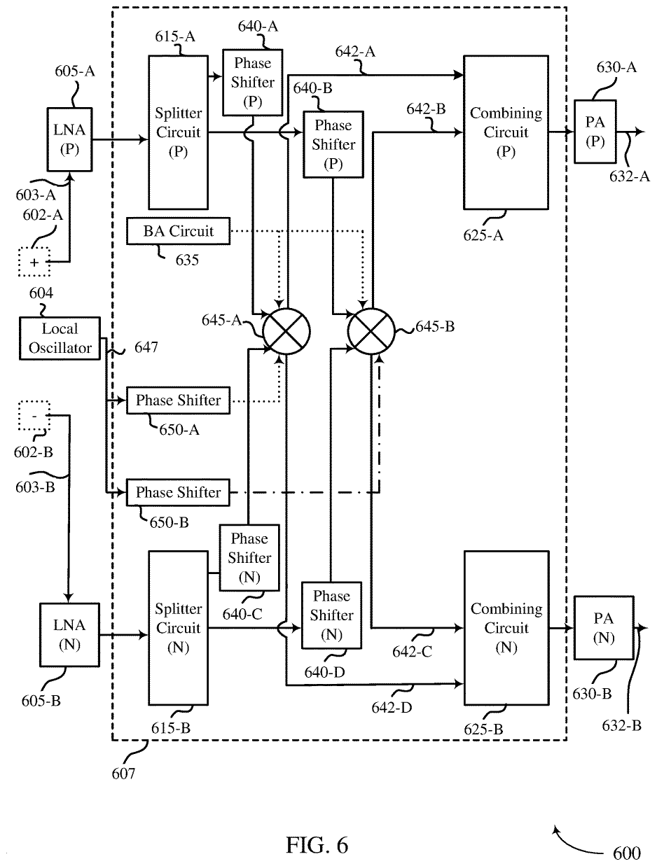

FIG. 6 shows an example of a satellite transponder signal diagram 600 that supports a low spurious down-conversion mixer in accordance with aspects of the present disclosure. Satellite transponder signal diagram 600 is a conceptual diagram that illustrates the differential nature of some of the components described herein. In some examples, satellite transponder signal diagram 600 may represent one or more aspects of satellite transponder signal diagrams 100 and/or 300 or satellite transponder 200. For instance, LNA 605-a and LNA 605-b may be an example of an LNA 110 as described with reference to FIG. 1, an LNA 210 as described with reference to FIG. 2, and/or an LNA 310 as described with reference to FIG. 3. LNA 605-a and LNA 605-b represent a positive phase portion and a negative phase portion, respectively, of a differential LNA. For example, a differential LNA may have positive and negative paths that share common bias and current sources for common mode rejection. Mixing circuit 607 may be an example of a mixing circuit 105 as described with reference to FIG. 1 and/or a mixing circuit 220 as described with reference to FIG. 2. splitter circuit 615-a and splitter circuit 615-b may be an example of a splitting circuit 130 as described with reference to FIG. 1. splitter circuit 615-a and splitter circuit 615-b represent a positive phase portion and a negative phase portion, respectively, of a differential splitter circuit. Any of phase shifters 640-a, 640-b, 640-c, and 640-d may be an example of a phase shifter 140 as described with reference to FIG. 1 and/or any of phase shifters 315 as described with reference to FIG. 3. phase shifter 640-a and phase shifter 640-c represent a positive phase portion and a negative phase portion, respectively, of a differential phase shifter. Likewise for phase shifter 640-b and phase shifter 640-d. Any of differential mixers 645-a and 645-b may be an example of a mixer 145 as described with reference to FIG. 1 and/or any of mixers 320 as described with reference to FIG. 3; any of second phase shifters 650-a and 650-b may be an example of a phase shifter 150 or phase shifter 315 as described with reference to FIG. 1 or 3; local oscillator 604 may be an example of a local oscillator 125 as described with reference to FIG. 1; combining circuit 625-a and combining circuit 625-b may be an example of a combining circuit 155 as described with reference to FIG. 1 and/or a combining circuit 355 as described with reference to FIG. 3. Combining circuit 625-a and combining circuit 625-b may represent a positive phase portion and a negative phase portion, respectively, of a differential phase shifter. PA 630-a and PA 630-b may be an example of a PA 115 as described with reference to FIG. 1, a PA 235 as described with reference to FIG. 2, and/or a PA 330 as described with reference to FIG. 3; or any combination thereof. PA 630-a and PA 630-b represent a positive phase portion and a negative phase portion, respectively, of a differential PA.

LNA 605-a may be coupled with a first differential port 602-a and mixing circuit 607. Mixing circuit 607 may include a splitter circuit 615-a coupled with LNA 605-a, phase shifter 640-a, and phase shifter 640-b. Phase shifter 640-a may be coupled with first differential mixer 645-a and phase shifter 640-b may be coupled with second differential mixer 645-b. Differential mixers 645-a and 645-b may be coupled with combining circuit 625-a of mixing circuit 607. Combining circuit 625-a may be coupled with PA 630-a.

LNA 605-b may be coupled with a second differential port 602-b and mixing circuit 607. Mixing circuit 607 may include a splitter circuit 615-b coupled with LNA 605-b, phase shifter 640-c, and phase shifter 640-d. Phase shifter 640-c may be coupled with differential mixer 645-a and phase shifter 640-d may be coupled with second differential mixer 645-b. Differential mixers 645-a and 645-b may be coupled with combining circuit 625-b of mixing circuit 607. Combining circuit 625-b may be coupled with PA 630-b.

Mixing circuit 607 may include one or more balance adjustment circuits. For instance, mixing circuit 607 may include balance adjustment circuit 635. Balance adjustment circuit 635 may be coupled with first differential mixer 645-a or second differential mixer 645-b, or both.

Mixing circuit 607 may include one or more phase shifters coupled with local oscillator 604. For instance, mixing circuit 607 may include phase shifter 650-a or phase shifter 650-b, or both. The oscillator signal from local oscillator 604 may be coupled with first differential mixer 645-a (e.g., via phase shifter 650-a if present) and second differential mixer 645-b (e.g., via phase shifter 650-b if present).

In some examples, satellite transponder signal diagram 600 may illustrate techniques for suppressing odd harmonics of an oscillator frequency by using less than a quantity of mixers corresponding to the order of the odd harmonics. For example, a fifth order odd harmonic may be suppressed using two double balanced mixers. For instance, LNA 605-a may receive a first signal 603-a from differential port 602-a and LNA 605-b may receive a second signal 603-b from differential port 602-b. The first signal 603-a and the second signal 603-b may be a differential pair of signals.

Local oscillator 604 may generate oscillator signal 647 and may provide the oscillator signal 647 to phase shifter 650-a or phase shifter 650-b, or both. Phase shifter 650-a may provide a first phase shifted representation of the oscillator signal 647 to first differential mixer 645-a and phase shifter 650-b may provide a second phase shifted representation of the oscillator signal 647 to second differential mixer 645-b. The oscillator signal 647 may be a single oscillator signal or a differential pair of signals.

LNA 605-a may amplify the first signal 603-a and may provide the first signal 603-a to splitter circuit 615-a of mixing circuit 607. Splitter circuit 615-a may split the first signal 603-a among phase shifters 640-a and 640-b. Phase shifter 640-a may provide a first phase shifted representation of first signal 603-a to first differential mixer 645-a, while phase shifter 640-b may provide a second phase shifted representation of first signal 603-a to second differential mixer 645-b.

LNA 605-b may amplify the second signal 603-b and may provide the second signal 603-b to splitter circuit 615-b of mixing circuit 607. Splitter circuit 615-b may send the second signal 603-b to phase shifter 640-c and phase shifter 640-d. Phase shifter 640-c may provide a first phase shifted representation of second signal 603-b to first differential mixer 645-a and phase shifter 640-d may provide a second phase shifted representation of second signal 603-b to second differential mixer 645-b.

First differential mixer 645-a may output first component signal 642-a to combining circuit 625-a and may output fourth component signal 642-d to combining circuit 625-b. Second differential mixer 645-b may output second component signal 642-b to combining circuit 625-a and may output third component signal 642-c to combining circuit 625-b. Each of first component signal 642-a and second component signal 642-b may be associated with first signal 603-a (e.g., associated with mixing respective phase shifted representations of first signal 603-a and respective phase shifted representations of the oscillator signal).

Combining circuit 625-a may sum or subtract the first component signal 642-a and the second component signal 642-b to generate third signal 632-a and may provide third signal 632-a to PA 630-a. PA 630-a may amplify third signal 632-a and may output the amplified third signal 632-a. Combining circuit 625-b may sum or subtract the third component signal 642-c and the fourth component signal 642-d to generate fourth signal 632-b and may provide fourth signal 632-b to PA 630-b. PA 630-b may amplify fourth signal 632-b and may output the amplified fourth signal 632-b.

In some examples, phase shifter 650-b may be used for the suppression of an odd harmonic. For example, the phase of phase shifter 650-b may be selected based on the order of the odd harmonic, and other phase shifters 640 and 650 may be used for calibration of other imbalances (e.g., path differences) within mixing circuit 607. In some cases, the phase of phase shifter 650-b may result in enhancement of an even order harmonic that would otherwise be suppressed due to first signal 603-a and second signal 603-b being a differential pair (e.g., using double balanced mixers). In some examples, using balance adjustment circuit 635 to adjust a balance (e.g., bias points for transistors within the double balanced mixers) of differential mixers may more effectively suppress the even harmonic of the oscillator frequency that was enhanced due to the phase difference of the oscillator signal between the two mixers. For instance, balance adjustment circuit 635 may adjust or calibrate a balance of first differential mixer 645-a, or second differential mixer 645-b, or both. In addition, in some cases phase shifters 640 may also include amplitude adjustment as is shown in FIG. 1, and the amplitude of the first signal 603-a, the second signal 603-b, or both, may be adjusted as part of adjusting the balance of differential mixers 645-a or 645-b to suppress the even order harmonic or otherwise enhance the performance of mixing circuit 607 (e.g., reduce suppression of the fundamental).

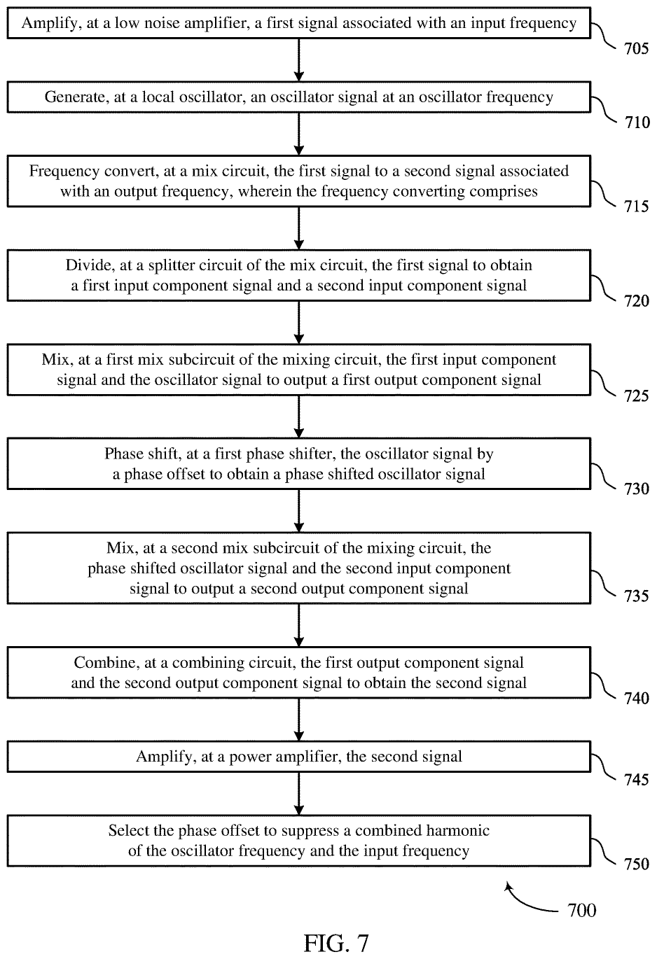

FIG. 7 shows a flowchart illustrating a method 700 that supports a low spurious down-conversion mixer in accordance with aspects of the present disclosure. The operations of the method 700 may be implemented by a satellite transponder or its components as described herein. For example, the operations of the method 700 may be performed by satellite transponder 200. In some examples, the satellite transponder 200 may execute a set of instructions to control the functional elements of the satellite transponder 200 to perform the described functions. Additionally, or alternatively, the satellite transponder 200 may perform aspects of the described functions using special-purpose hardware.

At 705, the method 700 may include amplifying, at a low noise amplifier, a first signal associated with an input frequency. The operations of 705 may be performed in accordance with examples as disclosed herein.

At 710, the method 700 may include generating, at a local oscillator, an oscillator signal at an oscillator frequency. The operations of 710 may be performed in accordance with examples as disclosed herein.

At 715, the method 700 may include frequency converting, at a mixing circuit, the first signal to a second signal associated with an output frequency, wherein the frequency converting comprises. The operations of 715 may be performed in accordance with examples as disclosed herein.

At 720, the method 700 may include dividing, at a splitter circuit of the mixing circuit, the first signal to obtain a first input component signal and a second input component signal. The operations of 720 may be performed in accordance with examples as disclosed herein.

At 725, the method 700 may include mixing, at a first mixing subcircuit of the mixing circuit, the first input component signal and the oscillator signal to output a first output component signal. The operations of 725 may be performed in accordance with examples as disclosed herein.

At 730, the method 700 may include phase shifting, at a first phase shifter, the oscillator signal by a phase offset to obtain a phase shifted oscillator signal. The operations of 730 may be performed in accordance with examples as disclosed herein.

At 735, the method 700 may include mixing, at a second mixing subcircuit of the mixing circuit, the phase shifted oscillator signal and the second input component signal to output a second output component signal. The operations of 735 may be performed in accordance with examples as disclosed herein.

At 740, the method 700 may include combining, at a combining circuit, the first output component signal and the second output component signal to obtain the second signal. The operations of 740 may be performed in accordance with examples as disclosed herein.

At 745, the method 700 may include amplifying, at a power amplifier, the second signal. The operations of 745 may be performed in accordance with examples as disclosed herein.

At 750, the method 700 may include selecting the phase offset to suppress a combined harmonic of the oscillator frequency and the input frequency. The operations of 750 may be performed in accordance with examples as disclosed herein.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

In some examples, an apparatus as described herein may perform a method or methods. The apparatus may include features, circuitry, logic, means, or instructions (e.g., a non-transitory computer-readable medium storing instructions executable by a processor), or any combination thereof for performing the following aspects of the present disclosure:

It should be noted that these methods describe examples of implementations, and that the operations and the steps may be rearranged or otherwise modified such that other implementations are possible. In some examples, aspects from two or more of the methods may be combined. For example, aspects of each of the methods may include steps or aspects of the other methods, or other steps or techniques described herein.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and modules described in connection with the disclosure herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The functions described herein may be implemented in hardware, software executed by a processor, firmware, or any combination thereof. If implemented in software executed by a processor, the functions may be stored on or transmitted over as one or more instructions or code on a computer readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

Computer readable media includes both non transitory computer storage media and communication media including any medium that facilitates transfer of a computer program from one place to another. A non-transitory storage medium may be any available medium that can be accessed by a general purpose or special purpose computer. By way of example, and not limitation, non-transitory computer readable media may include RAM, ROM, electrically erasable programmable read-only memory (EEPROM), flash memory, compact disk read-only memory (CDROM) or other optical disk storage, magnetic disk storage or other magnetic storage devices, or any other non-transitory medium that can be used to carry or store desired program code means in the form of instructions or data structures and that can be accessed by a general purpose or special purpose computer, or a general purpose or special purpose processor. Also, any connection is properly termed a computer readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk and Blu ray disc where disks usually reproduce data magnetically, while discs reproduce data optically with lasers. Combinations of the above are also included within the scope of computer readable media.

As used herein, including in the claims, “or” as used in a list of items (e.g., a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label, or other subsequent reference label.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details for the purpose of providing an understanding of the described techniques. These techniques, however, may be practiced without these specific details. In some instances, well known structures and devices are shown in block diagram form in order to avoid obscuring the concepts of the described examples.

The description herein is provided to enable a person skilled in the art to make or use the disclosure. Various modifications to the disclosure will be readily apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

1. A transponder, comprising:
a low noise amplifier configured to amplify a first signal associated with an input frequency;
a local oscillator configured to generate an oscillator signal at an oscillator frequency;
a mixing circuit coupled with the low noise amplifier and the local oscillator, wherein the mixing circuit is configured to frequency convert the first signal to a second signal associated with an output frequency, wherein the mixing circuit comprises:
a splitter circuit coupled with the low noise amplifier and configured to divide the first signal to obtain a first input component signal and a second input component signal;
a first mixing subcircuit configured to receive the first input component signal and the oscillator signal and to output a first output component signal;
a first phase shifter configured to phase shift the oscillator signal by a phase offset to output a phase shifted oscillator signal;
a second mixing subcircuit configured to receive the phase shifted oscillator signal and the second input component signal and to output a second output component signal; and
a combining circuit configured to combine the second output component signal and the first output component signal to obtain the second signal;
a power amplifier coupled with the mixing circuit and configured to amplify the second signal; and
a controller coupled with the mixing circuit, wherein the controller is configured to:
adjust the phase offset of the first phase shifter so that a mixing product of an odd harmonic of the oscillator frequency is suppressed by the combination of the second output component signal and the first output component signal, wherein the phase offset is adjusted from a phase that suppresses an even harmonic of the oscillator signal, and wherein the even harmonic of the oscillator signal is enhanced based on the phase offset; and
adjust one or more settings, wherein adjusting the one or more settings adjusts an imbalance of at least one of the first mixing subcircuit or the second mixing subcircuit to suppress the even harmonic of the oscillator signal, wherein to adjust the one or more of settings, the controller is configured to adjust one or more voltage bias points for one or more transistors within the at least one of the first mixing subcircuit or the second mixing subcircuit, wherein the first mixing subcircuit and the second mixing subcircuit comprise differential double balance mixers.

2-3. (canceled)

4. The transponder of claim 1, wherein the mixing product of the odd harmonic of the oscillator frequency comprises an intermodulation of an odd order harmonic of the oscillator frequency and the input frequency.

5. The transponder of claim 4, wherein the odd order harmonic of the oscillator frequency is a fifth order harmonic.

6. The transponder of claim 4, wherein the phase offset is based on an order of the odd order harmonic.

7. The transponder of claim 1, wherein the combining circuit is configured to sum the second output component signal and the first output component signal to obtain the second signal.

8. The transponder of claim 1, wherein the combining circuit is configured to subtract the second output component signal from the first output component signal to obtain the second signal.

9. The transponder of claim 1, wherein the first signal, the first input component signal, the second input component signal, the first output component signal, the second output component signal, and the second signal are differential pairs of signals.

10. The transponder of claim 1, further comprising:
a second phase shifter between the splitter circuit and the second mixing subcircuit, wherein the controller is configured to adjust a phase of the second phase shifter based on a path difference between the first mixing subcircuit and the second mixing subcircuit.

11. The transponder of claim 1, wherein the oscillator frequency is less than one half of the input frequency.

12. A method, comprising:
amplifying, at a low noise amplifier, a first signal associated with an input frequency;
generating, at a local oscillator, an oscillator signal at an oscillator frequency;
frequency converting, at a mixing circuit, the first signal to a second signal associated with an output frequency, wherein the frequency converting comprises:
dividing, at a splitter circuit of the mixing circuit, the first signal to obtain a first input component signal and a second input component signal;
mixing, at a first mixing subcircuit of the mixing circuit, the first input component signal and the oscillator signal to output a first output component signal;
phase shifting, at a first phase shifter, the oscillator signal by a phase offset to obtain a phase shifted oscillator signal;
mixing, at a second mixing subcircuit of the mixing circuit, the phase shifted oscillator signal and the second input component signal to output a second output component signal; and
combining, at a combining circuit, the first output component signal and the second output component signal to obtain the second signal;
amplifying, at a power amplifier, the second signal;
selecting the phase offset so that a mixing product of an odd harmonic of the oscillator frequency is suppressed by the combination of the second output component signal and the first output component signal, wherein the phase offset is adjusted from a phase that suppresses an even harmonic of the oscillator signal, and wherein the even harmonic of the oscillator signal is enhanced based on the phase offset; and
adjusting one or more settings, wherein adjusting the one or more settings adjusts an imbalance of at least one of the first mixing subcircuit or the second mixing subcircuit to suppress the even harmonic of the oscillator signal, wherein adjusting the one or more of settings comprises adjusting one or more voltage bias points for one or more transistors within the at least one of the first mixing subcircuit or the second mixing subcircuit, wherein the first mixing subcircuit and the second mixing subcircuit comprise differential double balance mixers.

13-14. (canceled)

15. The method of claim 12, further comprising:
iteratively adjusting the phase offset and the imbalance of the at least one of the first mixing subcircuit or the second mixing subcircuit based on one or more measurements of the mixing product of the odd harmonic of the oscillator frequency and the even harmonic.

16. The method of claim 12, wherein the mixing product of the odd harmonic of the oscillator frequency comprises an intermodulation of an odd order harmonic of the oscillator frequency and the input frequency.

17. The method of claim 16, wherein the odd order harmonic of the oscillator frequency is a fifth order harmonic.

18. The method of claim 16, wherein the phase offset is based on an order of the odd order harmonic.

19. The method of claim 12, wherein the combining circuit is configured to sum the second output component signal and the first output component signal to obtain the second signal.

20. The method of claim 12, wherein the combining circuit is configured to subtract the second output component signal from the first output component signal to obtain the second signal.

21. The method of claim 12, wherein the first signal, the first input component signal, the second input component signal, the first output component signal, the second output component signal, and the second signal are differential pairs of signals.

22. The method of claim 12, further comprising:
phase shifting, at a second phase shifter, a phase of the second input component signal based on a path difference between the first mixing subcircuit and the second mixing subcircuit.

23. The method of claim 12, wherein the oscillator frequency is less than one half of the input frequency.

24. The transponder of claim 1, wherein the mixing circuit comprises only two mixing subcircuits comprising the first mixing subcircuit and the second mixing subcircuit.

25. The method of claim 12, wherein the mixing circuit comprises only two mixing subcircuits comprising the first mixing subcircuit and the second mixing subcircuit.
